(19) United States
(12) Patent Application Publication
(10) Pub. No.: US 2018/0166448 A1
(43) Pub. Date: Jun. 14, 2018

(54) Strained-gate Engineered Dynamic Random Access Memory Including Ferroelectric Negative Capacitance Dielectrics And Manufacturing Method Thereof

(71) Applicant: National Taiwan Normal University, Taipei City (TW)

(72) Inventors: Chun-Hu Cheng, Tainan City (TW); Chun-Yen Chang, Taipei City (TW); Yu-Chien Chiu, Taipei City (TW)

(21) Appl. No.: 15/726,218

(22) Filed: Oct. 5, 2017

(30) Foreign Application Priority Data
Nov. 15, 2016 (TW) 105137313

(51) Int. Cl. H01L 27/108; H01L 29/51; H01L 49/02

(52) U.S. Cl. CPC H01L 27/10826; H01L 27/10879; H01L 28/40; H01L 29/516; H01L 27/10852

(57) ABSTRACT

A dynamic random access memory (DRAM) and a manufacturing method thereof are disclosed. A storage cell of the DRAM includes a FINFET and a capacitor. A gate of the FINFET is formed by a metal nitride or a carbonized metal having the effect of stress-induced strain. A gate dielectric of the FINFET and/or a dielectric of the capacitor can be formed by a ferroelectric material having negative capacitance characteristics. A strained-gate engineering is used in the invention achieve effects of (1) increasing ferro-electricity of the dielectric to enhance the operation speed and endurance of the FINFET; and (2) enhancing the ferro negative capacitance effect to improve the sub-threshold swing of the FINFET, so that the switching power and the off-current of the FINFET can be reduced and the charge retention capability of capacitor can be effectively enhanced to improve the operation characteristics of the DRAM.

### BACKGROUND OF THE INVENTION

### 1. Field of the Invention

This invention relates to dynamic random access memory (DRAM), especially to a strained-gate engineered DRAM including ferroelectric negative capacitance dielectrics and a manufacturing method thereof.

### 2. Description of the Prior Art

In general, all storage cells of the conventional DRAM have a structure of 1T1C, namely each storage cell includes a transistor and a capacitor. Its operating theorem is to use the transistor as a switch to control the charges flowing into the capacitor, and the amount of the charges stored in the capacitor represents whether a bit is 1 or 0. Since the static random access memory (SRAM) needs six transistors to process the data of one bit, but DRAM only needs one transistor and one capacitor to process the data of each bit, the DRAM can have very high density to store more in unit volume; therefore, the cost of DRAM is lower than that of SRAM.

In order to cope with various fields of application in the future, it is necessary to develop the storage cells of DRAM with fast operation speed and low power consumption. For example, a fin field-effect transistor (FINFET) can be used as the transistor of the storage cell in DRAM. Because the FINFET has larger driving current, the operation speed of the storage cells of DRAM can be effectively maintained.

However, with continuous development of Moore's Law, the size of semiconductor components should be also continued to shrink; therefore, the off-current (Ioff) of FINFET in the storage cell of DRAM will become larger and the charges stored in the capacitor of the storage cell of DRAM are easily lost, so that the data is difficult to be read. At this time, the FINFET has to continuously perform operations of refresh, and the power consumption of DRAM will be obviously increased.

### SUMMARY OF THE INVENTION

Therefore, the invention provides a strained-gate engineered DRAM including ferroelectric negative capacitance dielectrics and a manufacturing method thereof to solve the above-mentioned problems.

An embodiment of the invention is a DRAM manufacturing method for manufacturing a DRAM including a plurality of storage cells. Each storage cell includes a FINFET and a capacitor. The DRAM manufacturing method includes steps of: (a) using a ferroelectric material having negative capacitance characteristics to form a gate dielectric of the FINFET and/or a dielectric of the capacitor; (b) using a metal nitride or a carbonized metal having an effect of stress-induced strain to form a gate of the FINFET; and (c) performing a strained-gate engineering to enhance ferroelectric negative capacitance characteristics of the gate dielectric of the FINFET and/or the dielectric of the capacitor to improve operation characteristics of the DRAM.

In an embodiment, the metal nitride or the carbonized metal in the step (b) comprises TiN, TaN, TaCN, WN, TiWN, TiC, TiAlC, TaC, TaAlC or NbAlC.

In an embodiment, the ferroelectric material having negative capacitance characteristics in the step (a) includes HfSiO, PbZrTiO3, BaSrTiO3, SrBi2Ta2O9, PbLaZrTiO3, HfZrO, HfAlO, HfYO, HfGdO, HfSrO, HfNdO, HfSmO or HfLaO.

In an embodiment, the gate of the FINFET in the step (b) has a multi-layer metal structure, and a metal work function and a strain force of the gate are adjustable by changing nitrogen content in the metal nitride or carbon content in the carbonized metal.

In an embodiment, the gate dielectric of the FINFET and/or the dielectric of the capacitor in the step (c) affected by the strained-gate engineering becomes easier to change from a monoclinic phase to an orthorhombic phase to enhance the ferroelectric negative capacitance characteristics of the gate dielectric of the FINFET and/or the dielectric of the capacitor.

In an embodiment, improving operation characteristics of the DRAM in the step (c) comprises reducing sub-threshold swing (SS) and off-current of the FINFET in the DRAM, enhancing charge retention capability of the capacitor in the DRAM and reducing number of times and power consumption of refreshing performed by the FINFET in the DRAM.

In an embodiment, a laminated structure of the FINFET comprises a silicon substrate, a buffer layer, a ferroelectric layer, a charge trapping layer, an insulating layer and a metal gate layer from bottom to top, relative positions of the ferroelectric layer and the charge trapping layer are interchangeable, and the charge trapping layer and the insulating layer can be present or removed; when the charge trapping layer and the insulating layer is present, a maintaining time of operation of the DRAM can be extended and ferroelectric effect becomes weaker; when the charge trapping layer and the insulating layer is removed, ferroelectric polarization becomes stronger and operating speed is increased, but the maintaining time of the operation of the DRAM becomes shorter.

In an embodiment, the buffer layer and the insulating layer are formed by insulating material; the ferroelectric layer formed by the ferroelectric material having negative capacitance characteristics has ferroelectric characteristics and anti-ferroelectric characteristics at the same time and generates a polarized electric field; the charge trapping layer is formed by conductive material, semiconductor material, insulating material or graphene; the metal gate layer is formed by the metal nitride or the carbonized metal; the ferroelectric layer and the charge trapping layer are manufactured through chemical vapor deposition or physical vapor deposition.

In an embodiment, the insulating material forming the charge trapping layer is a high-K material comprising zirconium silicon oxide, silicon nitride, Tantalum oxide, silicon oxynitride, Barium strontium titanate, silicon carbide, silicon oxycarbide, hafnium oxide, hafnium silicon oxide, hafnium zirconium oxide, hafnium silicon oxynitride, zirconium oxide, titanium oxide, cerium oxide, lanthanum oxide, lanthanum aluminum oxide or aluminum oxide; the graphene forming the charge trapping layer has different structures comprising porous graphene, single-layered graphene or multi-layered graphene.

In an embodiment, a laminated structure of the capacitor comprises a first metal layer, a buffer layer, a ferroelectric layer, a charge trapping layer, an insulating layer and a second metal layer from bottom to top, relative positions of the ferroelectric layer and the charge trapping layer are interchangeable, and the charge trapping layer and the insulating layer can be present or removed; when the charge trapping layer and the insulating layer is present, a maintaining time of operation of the DRAM can be extended and ferroelectric effect becomes weaker; when the charge trapping layer and the insulating layer is removed, ferroelectric polarization becomes stronger and operating speed is increased, but the maintaining time of the operation of the DRAM becomes shorter.

In an embodiment, the first metal layer and the second metal layer are formed by the metal nitride or the carbonized metal; the buffer layer and the insulating layer are formed by insulating material; the ferroelectric layer formed by the ferroelectric material having negative capacitance characteristics has ferroelectric characteristics and anti-ferroelectric characteristics at the same time and generates a polarized electric field; the charge trapping layer is formed by conductive material, semiconductor material, insulating material or graphene; the ferroelectric layer and the charge trapping layer are manufactured through chemical vapor deposition or physical vapor deposition.

In an embodiment, the insulating material forming the charge trapping layer is a high-K material comprising zirconium silicon oxide, silicon nitride, Tantalum oxide, silicon oxynitride, Barium strontium titanate, silicon carbide, silicon oxycarbide, hafnium oxide, hafnium silicon oxide, hafnium zirconium oxide, hafnium silicon oxynitride, zirconium oxide, titanium oxide, cerium oxide, lanthanum oxide, lanthanum aluminum oxide or aluminum oxide; the graphene forming the charge trapping layer has different structures comprising porous graphene, single-layered graphene or multi-layered graphene.

Another embodiment of the invention is a dynamic random access memory (DRAM). In this embodiment, the DRAM includes a plurality of storage cells. Each storage cell includes a FINFET and a capacitor coupled to the FINFET. A gate of the FINFET is formed by a metal nitride or a carbonized metal having an effect of stress-induced strain, and a gate dielectric of the FINFET and/or a dielectric of the capacitor is formed by a ferroelectric material having negative capacitance characteristics, a strained-gate engineering is performed on the DRAM to enhance ferroelectric negative capacitance characteristics of the gate dielectric of the FINFET and/or the dielectric of the capacitor to improve operation characteristics of the DRAM.

Compared to the prior art, the DRAM and the DRAM manufacturing method in the invention use ferroelectric material having negative capacitance characteristics as the gate dielectric of the FINFET and/or the dielectric of the capacitor in the DRAM and use strained-gate engineering to achieve the following effects of:

(1) enhancing the ferroelectricity of the dielectrics to increase the operation speed and durability of the FINFET;

(2) enhancing the ferroelectric negative-capacitance effect to improve the sub-threshold swing of the FINFET and reduce the switching power consumption and off current of the FINFET, so that the charge storage capability of the capacitor in the DRAM can be effectively enhanced and the operation characteristic of the DRAM can be also improved.

The advantage and spirit of the invention may be understood by the following detailed descriptions together with the appended drawings.

### BRIEF DESCRIPTION OF THE DRAWINGS

FIG. 1 illustrates a circuit schematic diagram of a storage cell of DRAM.

FIG. 2 illustrates a cross-sectional schematic diagram of a FINFET and a capacitor forming the storage cell of DRAM.

FIG. 3 illustrates a structural schematic diagram of a FINFET.

FIG. 4 illustrates a flowchart of the DRAM manufacturing method in a preferred embodiment of the invention.

FIG. 5 illustrates hysteresis loops of hafnium zinc oxide and hafnium oxide and virtual and unstable auxiliary line simulated by Landau model to prove that hafnium zinc oxide has negative capacitance characteristics.

FIG. 6 illustrates energy/polarization curve having two local negative-slope regions representing the existence of negative capacitance effect.

FIG. 7 illustrates the crystal phase of material changing from metastable monoclinic phase to more stable orthorhombic phase representing the behavior of negative capacitance.

FIG. 8 illustrates the small memory window variation during the high-speed durable cycle.

FIG. 9 illustrates that the ferroelectric-antiferroelectric phase conversion in the programming state can be completed in 10 ns due to the rapid current response.

FIG. 10 illustrates the FINFET in the DRAM of the invention having steeper sub-threshold swing curve than that in the prior arts due to the effects of strained-gate engineering.

FIG. 11 illustrates that the ferroelectric material has negative capacitance characteristics and can reduce the sub-threshold swing.

FIG. 12 illustrates that the ferroelectric dielectric having negative capacitance characteristics can be switched in high-speed to maintain the operation speed of the storage cell of DRAM to charge the capacitor rapidly.

FIG. 13A and FIG. 13B illustrate a schematic diagram and a cross-sectional diagram of the laminated structure of the FINFET respectively.

FIG. 14 illustrates a cross-sectional diagram of the laminated structure of the capacitor.

### DETAILED DESCRIPTION OF THE INVENTION

The invention provides a strained-gate engineered DRAM including ferroelectric negative capacitance dielectrics and a manufacturing method thereof to effectively enhance the ferroelectric characteristics of dielectrics through the configuration of ferroelectric negative capacitance dielectrics and the operation of strained-gate engineering to increase the operation speed and durability of FINFET, and the ferroelectric negative capacitance effect can be also enhanced to improve the sub-threshold swing (SS) of FINFET and reduce the switching power consumption and off current of FINFET; therefore, the charge storage capability of capacitor in DRAM can be effectively enhanced and the operation characteristic of DRAM can be also improved.

A preferred embodiment of the invention is a DRAM manufacturing method. In this embodiment, the DRAM manufacturing method is used for manufacturing a DRAM. In general, the DRAM includes a plurality of storage cells, and plurality of storage cells can be arranged in a form of matrix, but not limited to this.

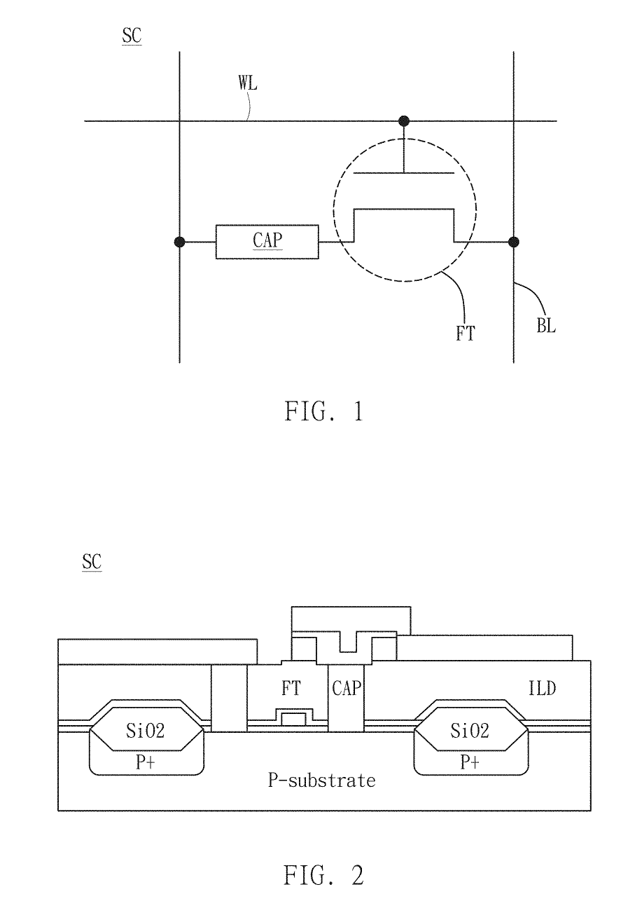

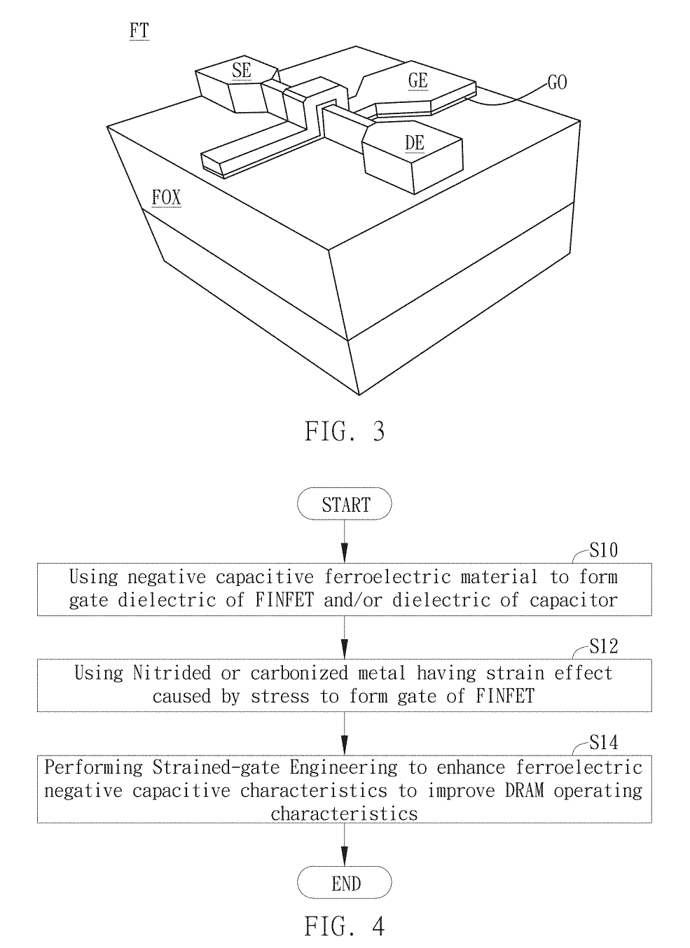

At first, please refer to FIG. 1. FIG. 1 illustrates a circuit schematic diagram of a storage cell of DRAM. As shown in FIG. 1, the storage cell SC of the DRAM includes a fin field-effect transistor (FINFET) FT and a capacitor CAP. The fin field-effect transistor FT and the capacitor CAP are coupled. A gate of the fin field-effect transistor FT is coupled to a word line WL and a source (or a drain) of the fin field-effect transistor FT is coupled to a bit line BL. FIG. 2 illustrates a cross-sectional schematic diagram of the fin field-effect transistor FT and the capacitor CAP forming the storage cell of the DRAM; FIG. 3 illustrates a structural schematic diagram of the fin field-effect transistor FT.

Then, please refer to FIG. 4. FIG. 4 illustrates a flowchart of the DRAM manufacturing method in this embodiment. AS shown in FIG. 4, the DRAM manufacturing method includes the following steps.

Step S10: using a ferroelectric material having negative capacitance characteristics to form a gate dielectric of the fin field-effect transistor and/or a dielectric of the capacitor, that is to say, the ferroelectric material can be used to form the gate dielectric of the fin field-effect transistor only, used to form the dielectric of the capacitor only, or used to form the gate dielectric of the fin field-effect transistor and the dielectric of the capacitor at the same time depending on practical needs;

Step S12: using a metal nitride or a carbonized metal having an effect of stress-induced strain to form a gate of the fin field-effect transistor;

Step S14: performing a strained-gate engineering to enhance ferroelectric negative capacitance characteristics of the gate dielectric of the fin field-effect transistor and/or the dielectric of the capacitor to improve operation characteristics of the DRAM and reduce power consumption.

In practical applications, the ferroelectric material having negative capacitance characteristics can include high-K materials such as HfSiO, HfZrO, HfAlO, HfYO, HfGdO, HfSrO or HfLaO, but not limited to this.

It should be noticed that each element doped in the above-mentioned HfO-based ferroelectric materials usually has a certain range of doping ratio; for example, the range of doping ratio for Zr is 30˜70%, the range of doping ratio for Al is 2˜12%, the range of doping ratio for Si is 2˜5%, the range of doping ratio for Y is 2˜12%, the range of doping ratio for La is 3˜6%, the range of doping ratio for Gd is 2˜6% and the range of doping ratio for Sr is 2˜6%, but not limited to this.

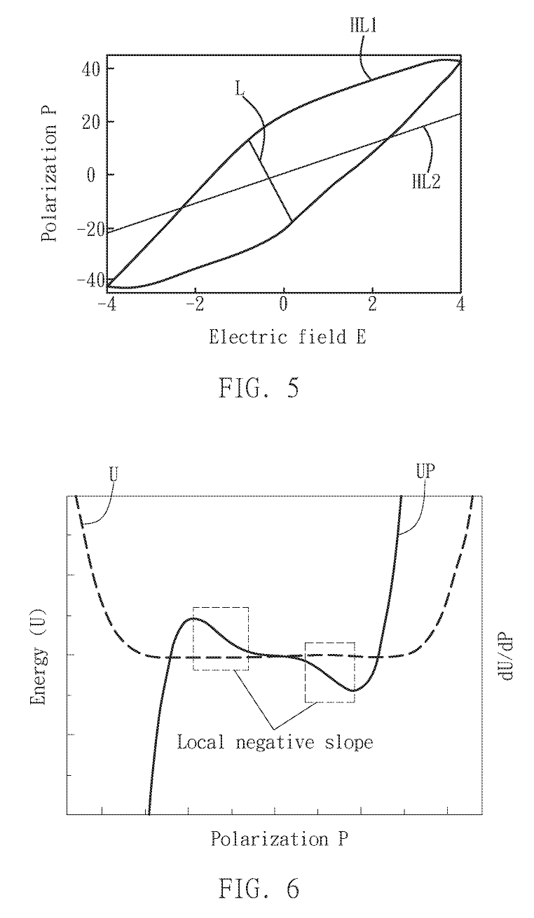

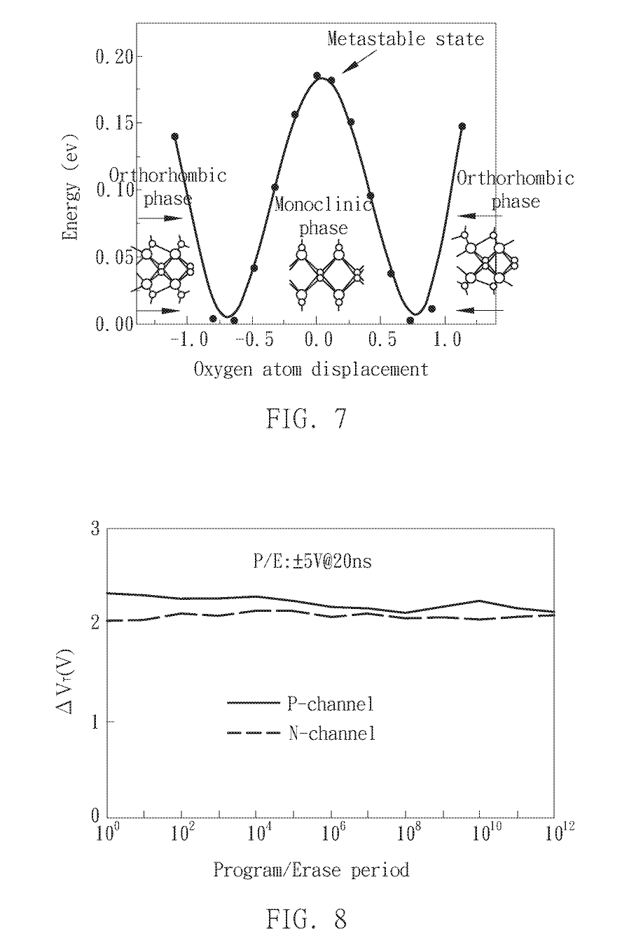

Please refer to FIG. 5, FIG. 6 and FIG. 7. FIG. 5, FIG. 6 and FIG. 7 show experimental results capable of proving the negative capacitance characteristics of material. As shown in FIG. 5, HL1 is a hysteresis loop of hafnium zinc oxide (HfZrO); HL2 is a hysteresis loop of hafnium oxide (HfO2); L is a virtual and unstable auxiliary line simulated by Landau model. Since (dP/dE) of the auxiliary line L is smaller than 0, it can prove that the ferroelectric material hafnium zinc oxide has negative capacitance characteristics. As shown in FIG. 6, since the energy/polarization (dU/dP) curve has two local negative slope regions, in the negative capacitance model, it represents that there is negative capacitance effect existed in the bi-stable potential well. As shown in FIG. 7, when the crystal phase of material changes from metastable monoclinic phase to more stable orthorhombic phase, it represents a behavior of negative capacitance.

In practical applications, the gate of the fin field-effect transistor in Step S12 has a multi-layer metal structure, and a metal work function and a strain force of the gate can be adjustable by changing nitrogen content in the metal nitride or carbon content in the carbonized metal, but not limited to this.

Taking TaN for example, during the deposition process of TaN, the ratio of Ar to N2 (Ar:N2) in the introduced gas should be within a certain range, such as 100:5˜100:15, so that the deposited TaN can have enough stress.

It should be noticed that when the gate dielectric of the fin field-effect transistor in Step S14 is affected by the strained-gate engineering, the gate dielectric will become easier to change from a metastable monoclinic phase to an orthorhombic phase to enhance the ferroelectric characteristics of the gate dielectric of the fin field-effect transistor. Therefore, the operation speed of the fin field-effect transistor can be increased and the durability of the fin field-effect transistor can be also enhanced.

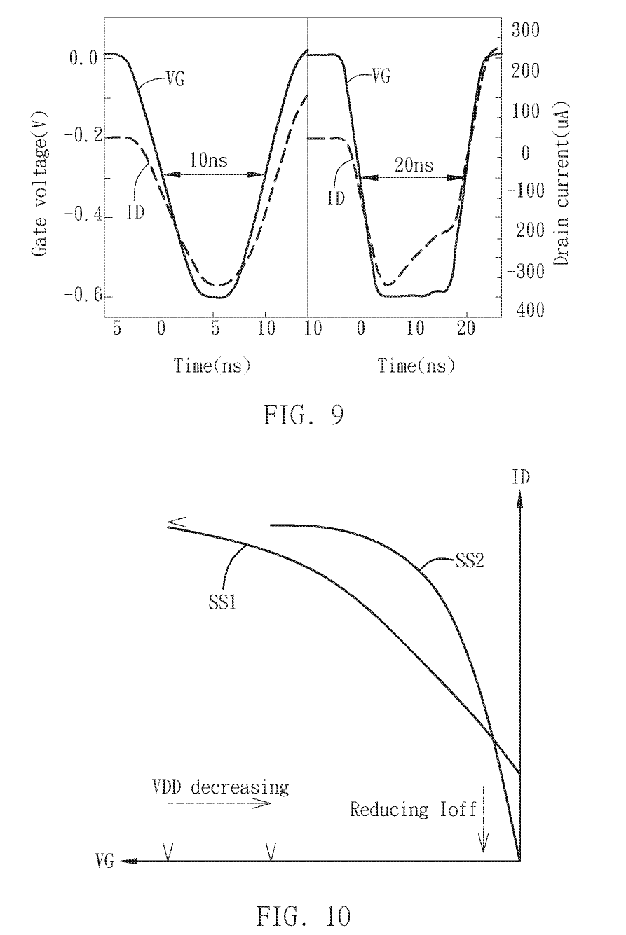

For example, as shown in FIG. 8, under the high-speed endurance cycling 20 ns, the memory window variation becomes very small. As shown in FIG. 9, the rapid current response discloses that the ferroelectric-antiferroelectric (FE-AFE) phase conversion in the programming state can be completed in 10 ns.

In addition, improving operation characteristics of the DRAM stated in Step S14 includes the following effects: reducing sub-threshold swing (SS) and off-current of the FINFET in the DRAM, enhancing charge retention capability of the capacitor in the DRAM, and reducing number of times and power consumption of refreshing performed by the FINFET in the DRAM, but not limited to this.

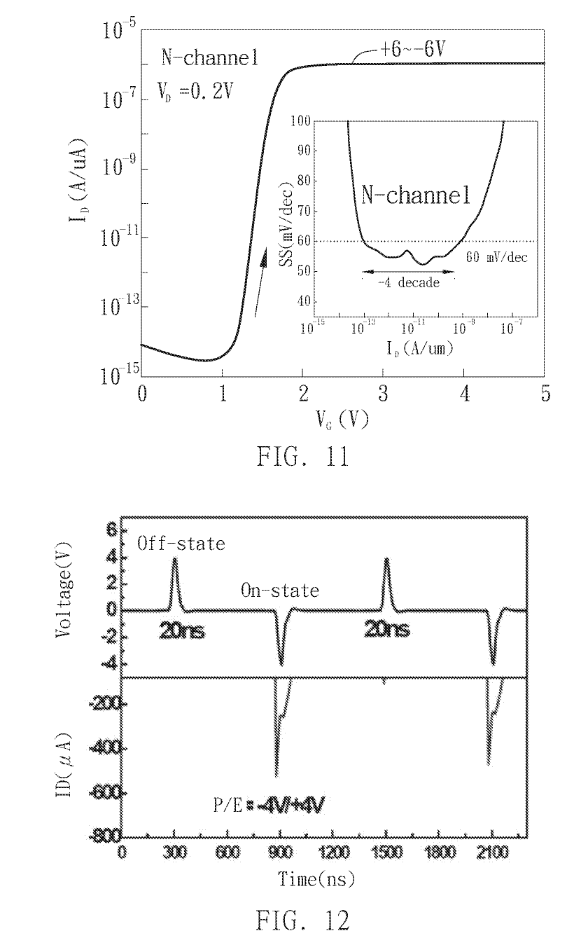

In detail, MOSFET is limited by the basic transistor physical phenomenon (minimum value of sub-threshold swing=60 mV/dec) and fails to further reduce operating voltage and switching power consumption; however, as shown in FIG. 10, compared to the sub-threshold swing curve SS1 of the conventional MOSFET limited by 60 mV/dec, the FINFET in the DRAM of the invention can have steeper sub-threshold swing curve SS2 (sub-threshold swing <60 mV/dec) than the sub-threshold swing curve SS1 of the conventional MOSFET because the ferroelectric negative-capacitance effect of the ferroelectric material having negative-capacitance characteristics of the invention is enhanced by the strained-gate engineering; therefore, the operating voltage (VDD) and switching power consumption of the FINFET can be reduced and the direct current off-current (Ioff) of the FINFET cam be also decreased.

Please refer to FIG. 11 and FIG. 12. FIG. 11 illustrates that the ferroelectric material has negative capacitance characteristics and can reduce the sub-threshold swing. FIG. 12 illustrates that the ferroelectric dielectric having negative capacitance characteristics can be switched in high-speed to maintain the operation speed of the storage cell of DRAM to charge the capacitor rapidly.

Another embodiment of the invention is a dynamic random access memory (DRAM). In this embodiment, the DRAM includes a plurality of storage cells. As shown in FIG. 1, each storage cell SC includes a fin field-effect transistor FT and a capacitor CAP coupled to the fin field-effect transistor FT. A gate of the fin field-effect transistor FT is coupled to a word line WL and a source (or a drain) of the fin field-effect transistor FT is coupled to a bit line BL. FIG. 2 illustrates a cross-sectional schematic diagram of the fin field-effect transistor FT and the capacitor CAP forming the storage cell of the DRAM; FIG. 3 illustrates a structural schematic diagram of the fin field-effect transistor FT.

It should be noticed that a gate of the fin field-effect transistor FT in each storage cell SC is formed by a metal nitride or a carbonized metal having an effect of stress-induced strain, and a gate dielectric of the fin field-effect transistor FT and/or a dielectric of the capacitor CAP is formed by a ferroelectric material having negative capacitance characteristics. In addition, a strained-gate engineering is performed on the DRAM to enhance ferroelectric negative capacitance characteristics of the gate dielectric of the fin field-effect transistor FT and/or the dielectric of the capacitor CAP to improve operation characteristics of the DRAM.

In practical applications, the ferroelectric material having negative capacitance characteristics can include high-K materials such as HfSiO, HfZrO, HfAlO, HfYO, HfGdO, HfSrO or HfLaO, but not limited to this.

In addition, the gate of the fin field-effect transistor can have a multi-layer metal structure, and a metal work function and a strain force of the gate can be adjustable by changing nitrogen content in the metal nitride or carbon content in the carbonized metal, but not limited to this. In practical applications, the metal nitride or the carbonized metal can include the metal nitride or the carbonized metal material such as TiN, TaN, TaCN, WN, TiWN, TiC, TiAlC, TaC, TaAlC or NbAlC, but not limited to this.

Then, different laminated structures of the fin field-effect transistor and the capacitor in the DRAM of the invention will be introduced as follows.

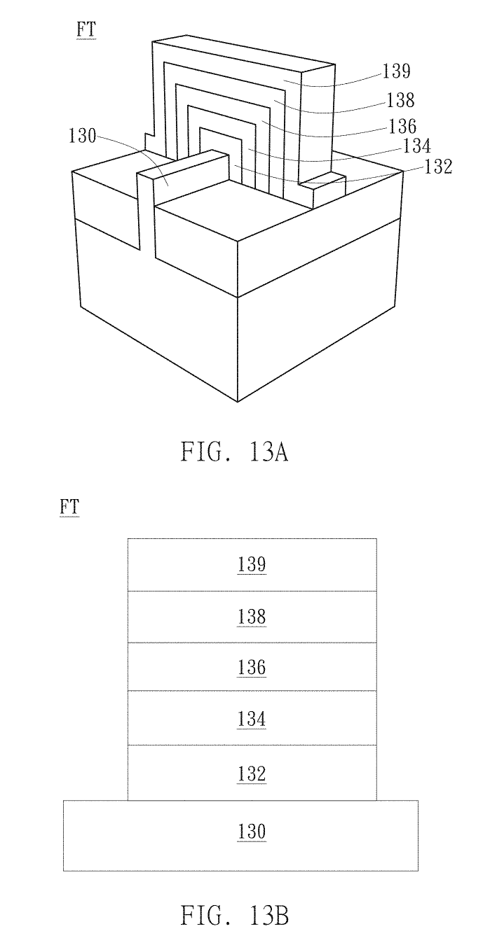

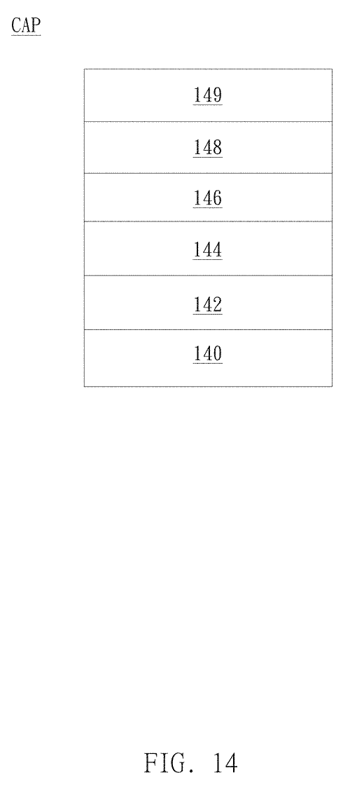

Please refer to FIG. 13A and FIG. 13B. FIG. 13A and FIG. 13B illustrate a schematic diagram and a cross-sectional diagram of the laminated structure of the fin field-effect transistor respectively. As shown in FIG. 13A and FIG. 13B, in an embodiment, the laminated structure of the fin field-effect transistor FT includes a silicon substrate 130, a buffer layer 132, a ferroelectric layer 134, a charge trapping layer 136, an insulating layer 138 and a metal gate layer 139 from bottom to top.

In practical applications, the relative positions of the ferroelectric layer 134 and the charge trapping layer 136 are interchangeable, and the charge trapping layer 136 and the insulating layer 138 can be present or removed. When the charge trapping layer 136 and the insulating layer 138 are present, a maintaining time of operation of the DRAM can be extended and the ferroelectric effect becomes weaker; when the charge trapping layer 136 and the insulating layer 138 are removed, the ferroelectric polarization will become stronger and the operating speed will be increased, but the maintaining time of the operation of the DRAM will become shorter. The buffer layer 132 and the insulating layer 138 can be formed by the insulating material; the ferroelectric layer 134 can be formed by the ferroelectric material having negative capacitance characteristics; the metal gate layer 139 can be formed by the metal nitride or the carbonized metal; the charge trapping layer 136 can be formed by conductive material, semiconductor material, insulating material or graphene.

It should be noticed that the ferroelectric layer 134 can be used to generate a polarized electric field and the ferroelectric layer 134 can have ferroelectric characteristics and anti-ferroelectric characteristics at the same time to obtain negative capacitance characteristics. The ferroelectric layer 134 can be manufactured through chemical vapor deposition (CVD) or physical vapor deposition (PVD), but not limited to this.

In addition, the charge trapping layer 136 can be also manufactured through chemical vapor deposition (CVD) or physical vapor deposition (PVD), but not limited to this.

In fact, the insulating material forming the charge trapping layer 136 can be high-K material such as zirconium silicon oxide, silicon nitride, Tantalum oxide, silicon oxynitride, Barium strontium titanate, silicon carbide, silicon oxycarbide, hafnium oxide, hafnium silicon oxide, hafnium zirconium oxide, hafnium silicon oxynitride, zirconium oxide, titanium oxide, cerium oxide, lanthanum oxide, lanthanum aluminum oxide or aluminum oxide, but not limited to this.

As to the graphene forming the charge trapping layer 136, it can have different structures such as porous graphene, single-layered graphene or multi-layered graphene, but not limited to this.

In addition, the ferroelectric material forming the ferroelectric layer 134 can be hafnium zirconium oxide, hafnium silicon oxide, lead zirconate titanate, barium strontium titanate, strontium bismuth tantalite, lead lanthanum zirconate titanate, hafnium aluminum oxide, hafnium yttrium oxide or HfO2 doped by Sr, Y, Zr, La, Nd, Sm or Gd, but not limited to this.

Please refer to FIG. 14. FIG. 14 illustrates a cross-sectional diagram of the laminated structure of the capacitor. As shown in FIG. 14, in an embodiment, the laminated structure of the capacitor CAP includes a first metal layer 140, a buffer layer 142, a ferroelectric layer 144, a charge trapping layer 146, an insulating layer 148 and a second metal layer 149.

In practical applications, the relative positions of the ferroelectric layer 144 and the charge trapping layer 146 are interchangeable, and the charge trapping layer 146 and the insulating layer 148 can be present or removed. When the charge trapping layer 146 and the insulating layer 148 are present, a maintaining time of operation of the DRAM can be extended and the ferroelectric effect becomes weaker; when the charge trapping layer 146 and the insulating layer 148 are removed, the ferroelectric polarization will become stronger and the operating speed will be increased, but the maintaining time of the operation of the DRAM will become shorter. The first metal layer 140 and the second metal layer 149 can be formed by the metal nitride or the carbonized metal; the buffer layer 142 and the insulating layer 148 can be formed by the insulating material; the ferroelectric layer 144 can be formed by the ferroelectric material having negative capacitance characteristics; the charge trapping layer 146 can be formed by conductive material, semiconductor material, insulating material or graphene.

It should be noticed that the ferroelectric layer 144 can be used to generate a polarized electric field and the ferroelectric layer 144 can have ferroelectric characteristics and anti-ferroelectric characteristics at the same time to obtain negative capacitance characteristics. The ferroelectric layer 144 can be manufactured through chemical vapor deposition (CVD) or physical vapor deposition (PVD), but not limited to this.

In addition, the charge trapping layer 146 can be also manufactured through chemical vapor deposition (CVD) or physical vapor deposition (PVD), but not limited to this.

In fact, the insulating material forming the charge trapping layer 146 can be high-K material such as zirconium silicon oxide, silicon nitride, Tantalum oxide, silicon oxynitride, Barium strontium titanate, silicon carbide, silicon oxycarbide, hafnium oxide, hafnium silicon oxide, hafnium zirconium oxide, hafnium silicon oxynitride, zirconium oxide, titanium oxide, cerium oxide, lanthanum oxide, lanthanum aluminum oxide or aluminum oxide, but not limited to this.

As to the graphene forming the charge trapping layer 146, it can have different structures such as porous graphene, single-layered graphene or multi-layered graphene, but not limited to this.

In addition, the ferroelectric material forming the ferroelectric layer 134 can be hafnium zirconium oxide, hafnium silicon oxide, lead zirconate titanate, barium strontium titanate, strontium bismuth tantalite, lead lanthanum zirconate titanate, hafnium aluminum oxide, hafnium yttrium oxide or HfO2 doped by Sr, Y, Zr, La, Nd, Sm or Gd, but not limited to this.

Compared to the prior art, the DRAM and the DRAM manufacturing method in the invention use ferroelectric material having negative capacitance characteristics as the gate dielectric of the FINFET and/or the dielectric of the capacitor in the DRAM and use strained-gate engineering to achieve the following effects of:

(1) enhancing the ferroelectricity of the dielectrics to increase the operation speed and durability of the FINFET;

(2) enhancing the ferroelectric negative-capacitance effect to improve the sub-threshold swing of the FINFET and reduce the switching power consumption and off current of the FINFET, so that the charge storage capability of the capacitor in the DRAM can be effectively enhanced and the operation characteristic of the DRAM can be improved.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A dynamic random access memory (DRAM) manufacturing method for manufacturing a DRAM comprising a plurality of storage cells, each storage cell comprising a fin field-effect transistor (FINFET) and a capacitor, the DRAM manufacturing method comprising steps of:
(a) using a ferroelectric material having negative capacitance characteristics to form a gate dielectric of the FINFET and/or a dielectric of the capacitor;
(b) using a metal nitride or a carbonized metal having an effect of stress-induced strain to form a gate of the FINFET; and
(c) performing a strained-gate engineering to enhance ferroelectric negative capacitance characteristics of the gate dielectric of the FINFET and/or the dielectric of the capacitor to improve operation characteristics of the DRAM.

2. The DRAM manufacturing method of claim 1, wherein the metal nitride or the carbonized metal in the step (b) comprises TiN, TaN, TaCN, WN, TiWN, TiC, TiAlC, TaC, TaAlC or NbAlC.

3. The DRAM manufacturing method of claim 1, wherein the ferroelectric material having negative capacitance characteristics in the step (a) comprises HfSiO, PbZrTiO3, BaSrTiO3, SrBi2Ta2O9, PbLaZrTiO3, HfZrO, HfAlO, HfYO, HfGdO, HfSrO, HfNdO, HfSmO or HfLaO.

4. The DRAM manufacturing method of claim 1, wherein the gate of the FINFET in the step (b) has a multi-layer metal structure, and a metal work function and a strain force of the gate are adjustable by changing nitrogen content in the metal nitride or carbon content in the carbonized metal.

5. The DRAM manufacturing method of claim 1, wherein the gate dielectric of the FINFET and/or the dielectric of the capacitor in the step (c) affected by the strained-gate engineering becomes easier to change from a monoclinic phase to an orthorhombic phase to enhance the ferroelectric negative capacitance characteristics of the gate dielectric of the FINFET and/or the dielectric of the capacitor.

6. The DRAM manufacturing method of claim 1, wherein improving operation characteristics of the DRAM in the step (c) comprises reducing sub-threshold swing (SS) and off-current of the FINFET in the DRAM, enhancing charge retention capability of the capacitor in the DRAM and reducing number of times and power consumption of refreshing performed by the FINFET in the DRAM.

7. The DRAM manufacturing method of claim 1, wherein a laminated structure of the FINFET comprises a silicon substrate, a buffer layer, a ferroelectric layer, a charge trapping layer, an insulating layer and a metal gate layer from bottom to top, relative positions of the ferroelectric layer and the charge trapping layer are interchangeable, and the charge trapping layer and the insulating layer can be present or removed; when the charge trapping layer and the insulating layer is present, a maintaining time of operation of the DRAM can be extended and ferroelectric effect becomes weaker; when the charge trapping layer and the insulating layer is removed, ferroelectric polarization becomes stronger and operating speed is increased, but the maintaining time of the operation of the DRAM becomes shorter.

8. The DRAM manufacturing method of claim 7, wherein the buffer layer and the insulating layer are formed by insulating material; the ferroelectric layer formed by the ferroelectric material having negative capacitance characteristics has ferroelectric characteristics and anti-ferroelectric characteristics at the same time and generates a polarized electric field; the charge trapping layer is formed by conductive material, semiconductor material, insulating material or graphene; the metal gate layer is formed by the metal nitride or the carbonized metal; the ferroelectric layer and the charge trapping layer are manufactured through chemical vapor deposition or physical vapor deposition.

9. The DRAM manufacturing method of claim 8, wherein the insulating material forming the charge trapping layer is a high-K material comprising zirconium silicon oxide, silicon nitride, Tantalum oxide, silicon oxynitride, Barium strontium titanate, silicon carbide, silicon oxycarbide, hafnium oxide, hafnium silicon oxide, hafnium zirconium oxide, hafnium silicon oxynitride, zirconium oxide, titanium oxide, cerium oxide, lanthanum oxide, lanthanum aluminum oxide or aluminum oxide; the graphene forming the charge trapping layer has different structures comprising porous graphene, single-layered graphene or multi-layered graphene.

10. The DRAM manufacturing method of claim 1, wherein a laminated structure of the capacitor comprises a first metal layer, a buffer layer, a ferroelectric layer, a charge trapping layer, an insulating layer and a second metal layer from bottom to top, relative positions of the ferroelectric layer and the charge trapping layer are interchangeable, and the charge trapping layer and the insulating layer can be present or removed; when the charge trapping layer and the insulating layer is present, a maintaining time of operation of the DRAM can be extended and ferroelectric effect becomes weaker; when the charge trapping layer and the insulating layer is removed, ferroelectric polarization becomes stronger and operating speed is increased, but the maintaining time of the operation of the DRAM becomes shorter.

11. The DRAM manufacturing method of claim 10, wherein the first metal layer and the second metal layer are formed by the metal nitride or the carbonized metal; the buffer layer and the insulating layer are formed by insulating material; the ferroelectric layer formed by the ferroelectric material having negative capacitance characteristics has ferroelectric characteristics and anti-ferroelectric characteristics at the same time and generates a polarized electric field; the charge trapping layer is formed by conductive material, semiconductor material, insulating material or graphene; the ferroelectric layer and the charge trapping layer are manufactured through chemical vapor deposition or physical vapor deposition.

12. The DRAM manufacturing method of claim 11, wherein the insulating material forming the charge trapping layer is a high-K material comprising zirconium silicon oxide, silicon nitride, Tantalum oxide, silicon oxynitride, Barium strontium titanate, silicon carbide, silicon oxycarbide, hafnium oxide, hafnium silicon oxide, hafnium zirconium oxide, hafnium silicon oxynitride, zirconium oxide, titanium oxide, cerium oxide, lanthanum oxide, lanthanum aluminum oxide or aluminum oxide; the graphene forming the charge trapping layer has different structures comprising porous graphene, single-layered graphene or multi-layered graphene.

13. A dynamic random access memory (DRAM), comprising:
a plurality of storage cells, each storage cell comprising:
a FINFET; and
a capacitor coupled to the FINFET;
wherein a gate of the FINFET is formed by a metal nitride or a carbonized metal having an effect of stress-induced strain, and a gate dielectric of the FINFET and/or a dielectric of the capacitor is formed by a ferroelectric material having negative capacitance characteristics, a strained-gate engineering is performed on the DRAM to enhance ferroelectric negative capacitance characteristics of the gate dielectric of the FINFET and/or the dielectric of the capacitor to improve operation characteristics of the DRAM.

14. The DRAM of claim 13, wherein the ferroelectric material having negative capacitance characteristics comprises HfSiO, PbZrTiO3, BaSrTiO3, SrBi2Ta2O9, PbLaZrTiO3, HfZrO, HfAlO, HfYO, HfGdO, HfSrO, HfNdO, HfSmO or HfLaO.

15. The DRAM of claim 13, wherein the metal nitride or the carbonized metal comprises TiN, TaN, TaCN, WN, TiWN, TiC, TiAlC, TaC, TaAlC or NbAlC.

16. The DRAM of claim 13, wherein the gate of the FINFET has a multi-layer metal structure, and a metal work function and a strain force of the gate are adjustable by changing nitrogen content in the metal nitride or carbon content in the carbonized metal.

17. The DRAM of claim 13, wherein the gate dielectric of the FINFET and/or the dielectric of the capacitor affected by the strained-gate engineering becomes easier to change from a monoclinic phase to an orthorhombic phase to enhance the ferroelectric negative capacitance characteristics of the gate dielectric of the FINFET and/or the dielectric of the capacitor.

18. The DRAM of claim 13, wherein improving operation characteristics of the DRAM comprises reducing sub-threshold swing (SS) and off-current of the FINFET in the DRAM, enhancing charge retention capability of the capacitor in the DRAM and reducing number of times and power consumption of refreshing performed by the FINFET in the DRAM.

19. The DRAM of claim 13, wherein a laminated structure of the FINFET comprises a silicon substrate, a buffer layer, a ferroelectric layer, a charge trapping layer, an insulating layer and a metal gate layer from bottom to top, relative positions of the ferroelectric layer and the charge trapping layer are interchangeable, and the charge trapping layer and the insulating layer can be present or removed; when the charge trapping layer and the insulating layer is present, a maintaining time of operation of the DRAM can be extended and ferroelectric effect becomes weaker; when the charge trapping layer and the insulating layer is removed, ferroelectric polarization becomes stronger and operating speed is increased, but the maintaining time of the operation of the DRAM becomes shorter.

20. The DRAM of claim 19, wherein the buffer layer and the insulating layer are formed by insulating material; the ferroelectric layer formed by the ferroelectric material having negative capacitance characteristics has ferroelectric characteristics and anti-ferroelectric characteristics at the same time and generates a polarized electric field; the charge trapping layer is formed by conductive material, semiconductor material, insulating material or graphene; the metal gate layer is formed by the metal nitride or the carbonized metal; the ferroelectric layer and the charge trapping layer are manufactured through chemical vapor deposition or physical vapor deposition.

21. The DRAM of claim 20, wherein the insulating material forming the charge trapping layer is a high-K material comprising zirconium silicon oxide, silicon nitride, Tantalum oxide, silicon oxynitride, Barium strontium titanate, silicon carbide, silicon oxycarbide, hafnium oxide, hafnium silicon oxide, hafnium zirconium oxide, hafnium silicon oxynitride, zirconium oxide, titanium oxide, cerium oxide, lanthanum oxide, lanthanum aluminum oxide or aluminum oxide; the graphene forming the charge trapping layer has different structures comprising porous graphene, single-layered graphene or multi-layered graphene.

22. The DRAM of claim 13, wherein a laminated structure of the capacitor comprises a first metal layer, a buffer layer, a ferroelectric layer, a charge trapping layer, an insulating layer and a second metal layer from bottom to top, relative positions of the ferroelectric layer and the charge trapping layer are interchangeable, and the charge trapping layer and the insulating layer can be present or removed; when the charge trapping layer and the insulating layer is present, a maintaining time of operation of the DRAM can be extended and ferroelectric effect becomes weaker; when the charge trapping layer and the insulating layer is removed, ferroelectric polarization becomes stronger and operating speed is increased, but the maintaining time of the operation of the DRAM becomes shorter.

23. The DRAM of claim 22, wherein the first metal layer and the second metal layer are formed by the metal nitride or the carbonized metal; the buffer layer and the insulating layer are formed by insulating material; the ferroelectric layer formed by the ferroelectric material having negative capacitance characteristics has ferroelectric characteristics and anti-ferroelectric characteristics at the same time and generates a polarized electric field; the charge trapping layer is formed by conductive material, semiconductor material, insulating material or graphene; the ferroelectric layer and the charge trapping layer are manufactured through chemical vapor deposition or physical vapor deposition.

24. The DRAM of claim 23, wherein the insulating material forming the charge trapping layer is a high-K material comprising zirconium silicon oxide, silicon nitride, Tantalum oxide, silicon oxynitride, Barium strontium titanate, silicon carbide, silicon oxycarbide, hafnium oxide, hafnium silicon oxide, hafnium zirconium oxide, hafnium silicon oxynitride, zirconium oxide, titanium oxide, cerium oxide, lanthanum oxide, lanthanum aluminum oxide or aluminum oxide; the graphene forming the charge trapping layer has different structures comprising porous graphene, single-layered graphene or multi-layered graphene.
